(19) United States
(12) Patent Application Publication
(10) Pub. No.: US 2008/0289685 A1
(43) Pub. Date: Nov. 27, 2008

(54) Thin Film Solar Cell with Rough Surface Layer Formed by Nano/Micro Particle Conductor Balls

(76) Inventors: Chii-Chang Chen, Jhongli City (TW); Shih-Shou Lo, Jhongli City (TW)

Correspondence Address: HDSL, P.O. BOX 220746, CHANTILLY, VA, 20153-0746, US

(21) Appl. No.: 11/752,289

(22) Filed: May 22, 2007

(51) Int. Cl. H01L 31/0216

(52) U.S. Cl. 136/256; 977/948

(57) ABSTRACT

A thin film solar cell has a rough surface layer formed by nano/micro particle conductor balls, which is provided by a method of producing a textured surface for a conductive layer of the solar cell by mounting the nano/micro particle conductor balls with a particle diameter of 50 nm to 150 nm onto the conductive layer by spray coating, spin coating, dip coating, natural deposition or gain, and a monolayer or multilayer self-assembled or random textured structure is achieved and applied in a thin film solar cell, so as to effectively reduce the thickness of an intrinsic semiconductor and greatly lower the manufacturing cost of the solar cell.

### FIELD OF THE INVENTION

The present invention relates to a thin film solar cell with a rough surface layer formed by nano/micro particle conductor balls, and more particularly to a thin film solar cell that mounts nano/micro particle conductor balls with a particle diameter of 50 nm to 150 nm onto a conductive layer to naturally form a random or periodic textured structure, so as to replace the traditional way of producing a random textured structure, reduce the thickness of the thin film solar cell and lower the manufacturing cost.

### BACKGROUND OF THE INVENTION

As energy resources are exhausted gradually, solar power generation has become a development target for all countries in the world. At present, silicon solar cell is still a mainstream product in the market, but the silicon solar cell requires a thickness greater than that of a thin film solar cell. In addition, the thin film solar cell is made of less material, and thus the thin film solar cell has high potentials for future development.

To effectively enhance the optical path, the thin film solar cell increases the conversion efficiency, and a structure having a periodic grating formed on a conductive layer by photolithography is developed, or special gases are used for producing a random textured structure by dry, wet, acidic or alkaline etching. However, the aforementioned methods used in the manufacturing procedure are more complicated, and thus incurring a higher manufacturing cost.

In view of the shortcomings and deficiencies of the prior art and the business opportunity of a solar cell that requires a higher solar cell efficiency and a lower production cost, the inventor of the present invention based on years of experience in the related industry to conduct extensive researches and experiments, and finally developed a thin film solar cell with a rough surface layer formed by nano/micro particle conductor balls with a particle diameter of 50 nm to 150 nm to overcome the foregoing shortcomings of the prior art and meet the requirements of the market.

### SUMMARY OF THE INVENTION

The present invention is to provide a thin film solar cell that mounts nano/micro particle conductor balls with a particle diameter of 50 nm to 150 nm on a conductive layer to naturally form a random textured structure and replace the traditional way of producing a periodic grating by photolithography. The random textured structure is produced by etching, and the structure of the nano/micro particle conductor balls with a particle diameter of 50 nm to 150 nm is a monolayer or a multiple-layer self-assembled or random textured structure, so that the thickness of the solar cell can be reduced, and the manufacturing cost can be lowered effectively.

### BRIEF DESCRIPTION OF THE DRAWING

FIG. 1 is a schematic view of a structure of a thin film solar cell with a rough surface layer formed by nano/micro particle conductor balls in accordance with the present invention.

### DETAILED DESCRIPTION OF THE PREFERRED EMBODIMENTS

To make it easier for our examiner to understand the objective of the invention, its structure, innovative features, and performance, we use a preferred embodiment together with the attached drawings for the detailed description of the invention.

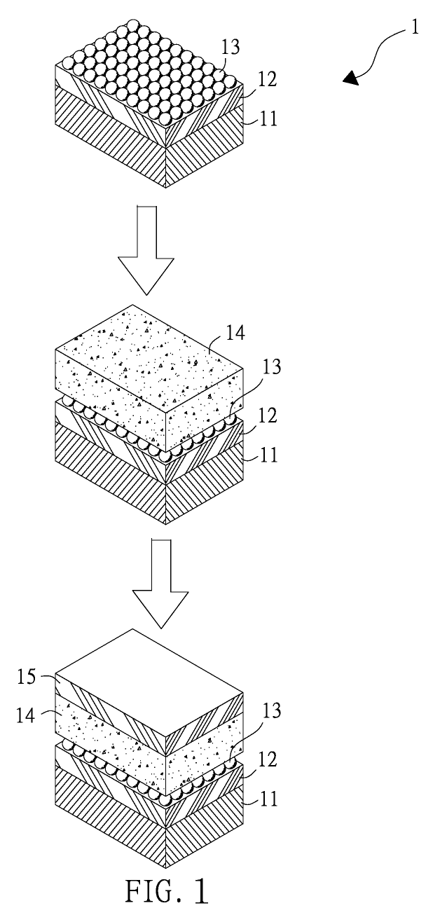

Referring to FIG. 1 for a thin film solar cell with a rough surface layer formed by nano/micro particle conductor balls in accordance with the present invention, the thin film solar cell 1 includes a conductive layer with a textured surface, which is unlike those made by a traditional photolithographic process or special gases and acid or alkaline solutions. The nano/micro particle conductor balls 13 with a particle diameter of 50 nm to 150 nm are mounted on the thin film solar cell 1 in the manufacturing flow as described below:

Firstly, a substrate 11 is prepared, and the substrate 11 can be made of glass, quartz or any other non-conductive material, and a conductive layer 12 is formed on the substrate 11, and the conductive layer 12 can be made of a p-type or n-type semiconductor used for any thin film solar cell manufacturing process.

And then, nano/micro particle conductor balls 13 with a particle diameter of 50 nm to 150 nm are mounted onto a conductive layer 12 by spray coating, spin coating, dip coating, natural deposition or gain, wherein the structure having the nano/micro particle conductor balls 13 with a particle diameter of 50 nm to 150 nm can be a monolayer or multilayer self-assembled or random textured structure, and the nano/micro particle conductor balls 13 is made of a conductive nano/micro material such as nickel oxide (NiO) and titanium dioxide (TiO₂), and the nano/micro particle conductor balls with a particle diameter of 50 nm to 150 nm have the same effect as the random textured structure produced by the conventional method.

And then, intrinsic semiconductors required in the manufacture of the thin film solar cell 1 of the invention are formed and covered onto the nano/micro particle conductor balls 13 by physical vapor deposition (PVD), chemical vapor deposition (CVD) or chemical synthesis to form an intrinsic semiconductor layer 14 for absorbing sunlight.

Finally, another conductive layer 15 is made of a p-type or n-type semiconductor, and such conductive layer 15 can be made of any material used in the manufacturing process of a thin film solar cell.

With the aforementioned manufacturing process, the nano/micro particle conductor balls 13 with a particle diameter of 50 nm to 150 nm can be applied in the thin film solar cell 1 to form a rough surface layer therein.

The improvements made by the thin film solar cell with a rough surface layer formed by nano/micro particle conductor balls 1 in accordance with the present invention are listed as follows:

1. As to usefulness, the thin film solar cell of the invention effectively reduces the thickness and improves the overall efficiency. In a present widely used conventional method, a textured structure is produced on a conductive layer by a photolithographic process or special gases and acidic or alkaline solutions. The invention mounts nano/micro particle conductor balls with a particle diameter of 50 nm to 150 nm onto a conductive layer to form the required structure. Thus, the invention is useful.

2. As to novelty, the invention mounts nano/micro particle conductor balls with a particle diameter of 50 nm to 150 nm on a conductive layer, and the nano/micro particle conductor balls with a particle diameter of 50 nm to 150 nm applied in a thin film solar cell can greatly improve the traveling path of sunlight into the thin film solar cell, so that the optical absorption of an intrinsic semiconductor layer of the thin film solar cell is enhanced effectively, and the overall conversion efficiency is improved. Thus, the invention is novel.

3. As to improvement, the invention mounts the nano/micro particle conductor balls with a particle diameter of 50 nm to 150 nm on a conductive layer, and the technology of mounting the nano/micro particle conductor balls with a particle diameter of 50 nm to 150 nm is simpler and easier than the traditional way, so that the manufacturing cost can be lowered substantially. Thus, the invention improves over the prior art.

In summation of the description above, the present invention herein enhances the performance than the conventional structure and further complies with the patent application requirements and is duly submitted for patent application.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A thin film solar cell with a rough surface layer formed by nano/micro particle conductor balls, comprising:
a substrate;
a first conductive layer, covered onto the substrate;
a plurality of nano/micro particle conductor balls, mounted onto the conductive layer;
an intrinsic semiconductor layer, covered on the nano/micro particle conductor balls; and
a second conductive layer, covered on the intrinsic semiconductor layer.

2. The thin film solar cell with a rough surface layer formed by nano/micro particle conductor balls of claim 1, wherein the conductive layer is a p-type or n-type semiconductor used in a thin film solar cell manufacturing process.

3. The thin film solar cell with a rough surface layer formed by nano/micro particle conductor balls of claim 1, wherein the second conductive layer is used in a thin film solar cell manufacturing process.

4. The thin film solar cell with a rough surface layer formed by nano/micro particle conductor balls of claim 1, wherein the nano/micro particle conductor balls are mounted by spraying, spinning, dip coating, natural deposition or gain.

5. The thin film solar cell with a rough surface layer formed by nano/micro particle conductor balls of claim 1, wherein the nano/micro particle conductor ball is a monolayer or multilayer self-assembled or random textured structure.

6. The thin film solar cell with a rough surface layer formed by nano/micro particle conductor balls of claim 1, wherein the thin film solar cell is covered by physical vapor deposition (PVD), chemical vapor deposition (CVD) or chemical synthesis.

7. The thin film solar cell with a rough surface layer formed by nano/micro particle conductor balls of claim 1, wherein the substrate is made of glass, quartz.

8. The thin film solar cell with a rough surface layer formed by nano/micro particle conductor balls of claim 1, wherein the nano/micro particle conductor ball is made of nickel oxide (NiO) or titanium dioxide (TiO₂).

9. The thin film solar cell with a rough surface layer formed by nano/micro particle conductor balls of claim 1, wherein the nano/micro particle conductor ball has a particle diameter of 50 nm to 150 nm.
